(19) United States
(12) Patent Application Publication
(10) Pub. No.: US 2013/0206210 A1
(43) Pub. Date: Aug. 15, 2013

(54) SOLAR BATTERY MODULE, PHOTOVOLTAIC APPARATUS, AND MANUFACTURING METHOD OF SOLAR BATTERY MODULE

(71) Applicants: Daisuke Niinobe, Tokyo (JP); Shigeru Matsuno, Tokyo (JP)

(72) Inventors: Daisuke Niinobe, Tokyo (JP); Shigeru Matsuno, Tokyo (JP)

(73) Assignee: Mitsubishi Electric Corporation, Tokyo (JP)

(21) Appl. No.: 13/877,594

(22) PCT Filed: Oct. 6, 2010
(86) PCT No.: PCT/JP2010/067591

§ 371 Date: Apr. 3, 2013

(51) Int. Cl. H01L 31/052

(52) U.S. Cl. CPC H01L 31/0527
USPC 136/246; 438/65; 136/256

(57) ABSTRACT

A solar battery module includes a device array, a substrate, a first sealing portion, a rear-surface protective member, a second sealing portion, and a light scattering portion. The light scattering portion has wavelength selectivity such that an optical reflectivity is not more than 15% over a wavelength region of 500 nanometers to 600 nanometers inclusive, and an optical reflectivity becomes larger than 15% in a wavelength region overlapping on an absorption wavelength range of the photovoltaic device in one of wavelength regions of not more than 350 nanometers and equal to or larger than 700 nanometers, and total integrated scattering of the light scattering portion becomes equal to or larger than 50% in the wavelength region overlapping on the absorption wavelength range of the photovoltaic device in one of the wavelength regions of not more than 350 nanometers and equal to or larger than 700 nanometers.

### FIELD

The present invention relates to a solar battery module, a photovoltaic apparatus, and a manufacturing method of a solar battery module.

### BACKGROUND

A photovoltaic device is used in a state of a module, which is sealed by a resin between a transparent glass substrate and a rear-surface protective member, in order to improve its weather resistance. In this case, the photovoltaic device is frequently installed with a gap between photovoltaic devices, in view of ease of arrangement of the photovoltaic devices and electric wiring. Light passing through the gap between the photovoltaic devices, among the light incident on the surface of the glass substrate (a light receiving surface), cannot contribute to power generation by the photovoltaic devices.

To improve power output of the solar battery module by using light passing through the gap between the photovoltaic devices, among the light incident on the surface of the glass substrate (the light receiving surface), it can be considered to arrange a member having a high optical reflectance on a rear side of the solar battery module so that light passing through the gap between the photovoltaic devices is reflected toward the light receiving surface in the module, and is caused to enter into the photovoltaic devices by reflecting the light again on a glass surface on the light receiving surface side or the like.

As the member having a high optical reflectance, a material having a high optical reflectance in a wide wavelength region including a visible light region is used. Therefore, the color tone thereof becomes white or the like. On the other hand, the photovoltaic device often becomes black in order to maximize absorption of light. Therefore, when the solar battery module is viewed from the light receiving surface side, the photovoltaic devices and the gap between the photovoltaic devices have a different color tone, thereby deteriorating design characteristics of the solar battery module.

To improve the design characteristics, it can be considered to arrange a member, which is colored black by a black pigment such as carbon black to absorb visible light on the rear side of the solar battery module.

In the member that absorbs visible light, the black pigment absorbs light and converts light to heat. Therefore, the temperature of the solar battery module rises, thereby reducing the power output of the solar battery module. Furthermore, because almost all the light passing through the gap between the photovoltaic devices is not used, the power output is reduced considerably than a case where a member having a high optical reflectance is arranged.

Patent Literature 1 describes a technique in which, in an infrared reflective laminated body, a black-colored resin layer is laminated on one surface of a base material layer by an infrared-transparent perylene black pigment, and a white-colored resin layer is laminated on the other surface of the base material layer by an infrared reflective white pigment. The black-colored resin layer absorbs visible light to express a colored appearance and transmits infrared light to the inside, and the transmitted infrared light is reflected by the white-colored resin layer, which then passes through the base material layer and the black-colored resin layer and is radiated. Therefore, according to Patent Literature 1, even if the laminated body is colored black or has a chromatic color, infrared light of a specific wavelength can be reflected to prevent heat accumulation.

Patent Literature 2 describes a technique in which, in an optical thin-film structure, an optical thin-film laminated body in which an infrared-light reflective layer, a spacer layer, and an absorber that absorbs visible light are sequentially laminated is formed on a substrate. In this optical thin-film structure, light reflected by the infrared-light reflective layer and light partially reflected by the absorber interfere with each other. Therefore, according to Patent Literature 2, a low reflectance is achieved in a visible region and a near-infrared region, and a high reflectance and high emissivity can be achieved in an infrared region and a far-infrared region, thereby enabling to realize a good solar absorber.

Patent Literature 3 describes a technique in which, in a solar battery module, a solar battery element is put between a translucent surface member and a weather resistant film via a translucent filling material, and the weather resistant film is formed stepwise. When the solar battery module is installed on a roof, the sunlight is not directly irradiated onto a surface in a direction of an eave in the weather resistant film, and in many cases, only scattering light is irradiated. Because an observer on the ground visually confirms only the surface in the direction of the eave in the weather resistant film, the weather resistant film is viewed as a low reflective color. Therefore, according to Patent Literature 3, both the light receiving surface of the solar battery module and the surface in the direction of the eave of the weather resistant film observed from between the solar battery elements seem like low reflective color, and thus it is possible to suppress damaging of the installation appearance by a color difference between them.

### CITATION LIST

### Patent Literatures

Patent Literature 1: Japanese Patent Application Laid-open No. 2009-119864
Patent Literature 2: Specification of United States Patent Application Publication No. 2006/0023327
Patent Literature 3: Japanese Patent Application Laid-open No. 2005-209957

### SUMMARY

### Technical Problem

As described above, it is difficult to balance improvement of the power output of the solar battery module with improvement of the design characteristics.

In Patent Literature 1, it is described that in the solar battery module using a back sheet for solar battery applying the infrared reflective laminated body, a transparent substrate, a sealing film, solar battery elements, a sealing film, and a back sheet for solar battery are sequentially laminated from the light receiving surface side of the sunlight. In the solar battery module, infrared light having entered into the transparent substrate and having passed through the gap between the solar battery elements is incident on the back sheet for solar battery. At this time, because infrared light passes through the black-colored resin layer and the base material layer twice, respectively, before and after the infrared light is reflected by the white-colored resin layer and is attenuated (partially absorbed), infrared light having sufficient strength may not be caused to enter into the solar battery module. Accordingly, the power output of the solar battery module is likely to be reduced.

Furthermore, in Patent Literature 1, only heat radiation by infrared reflection is described, and there is no description of contribution to power generation by reflecting light other than the visible light, and the structure thereof does not always contribute to power generation efficiently. For example, among light reflected by a reflecting layer, a light component in which an incident angle to a module surface becomes equal to or larger than a critical angle is totally reflected on the module surface, and can be caused to re-enter into the photovoltaic device. However, the reflecting layer and a visible-light absorbing layer are present as different two layers, and if light reflection on the reflecting layer is due to scattering, the light reflected by the reflecting layer is reflected on the visible-light absorbing layer or an interface between the visible-light absorbing layer and the module sealing material, and does not always contribute to power generation efficiently.

In Patent Literature 2, solar heat absorption having both a visible-light absorbing characteristic and an infrared reflection characteristic is described. However, there is no description of solar power generation using reflected infrared light. Even if such a film is directly used for the back sheet or the like of the solar battery module, reflected infrared light is not guided to the solar battery element effectively, and thus it is considered that the power output cannot be improved.

Furthermore, in the optical thin-film structure described in Patent Literature 2, because infrared light incident on the optical thin-film laminated body passes through the absorber and a spacer layer twice, respectively, before and after the infrared light is reflected by an infrared reflecting layer and is attenuated (partially absorbed), infrared light having sufficient strength may not be radiated by the optical thin-film laminated body. Accordingly, when the optical thin-film structure is applied to the solar battery module, the power output of the solar battery module is likely to be reduced.

Meanwhile, in the technique described in Patent Literature 3, because the sunlight is directly irradiated onto the surface in the direction of the eave in the weather resistant film depending on the solar altitude, which changes throughout the year, the weather resistant film may be observed as a color close to white from an observer on the ground. Furthermore, when the solar battery module is installed at a position lower than the eye level of the observer on the ground, because the observer on the ground visually confirms the surface in the direction of a ridge, on which the sunlight is directly irradiated, in the weather resistant film, the weather resistant film may be also observed as a color close to white from the observer on the ground. The surface of glass used for the surface of the solar battery module generally is not flat but has irregularities to prevent glare. Therefore, light having reached the glass surface from the inside of the module enters into the glass surface locally with an angle equal to or smaller than the critical angle, and there is a portion gap between the solar battery elements appears bright. Accordingly, the color tone of the light receiving surface of the solar battery element considerably different from that of the surface in the direction of the eave of the weather resistant film observed from between the solar battery elements, and the design characteristics of the solar battery module may be deteriorated.

Furthermore, in Patent Literatures 1 to 3, there is no description as to how to approximate the color tone of a metal electrode and the color tone of a light absorbing portion on a surface on a light incident side of the photovoltaic device. Most types of metal reflect visible light due to plasma reflection, and thus when the solar battery module is observed from the light receiving surface side of the substrate, the metal electrode and the light absorbing portion on the surface on the light incident side of the photovoltaic device have different color tones, thereby deteriorating the design characteristics of the solar battery module and the photovoltaic apparatus.

The present invention has been achieved to solve the above problems, and an object of the present invention is to provide a solar battery module, a photovoltaic apparatus, and a manufacturing method of a solar battery module that can improve power output of the solar battery module, and can improve design characteristics of the solar battery module.

### Solution to Problem

In order to solve the above problem and in order to attain the above object, a solar battery module according to a first aspect of the present invention includes: a device array in which a plurality of photovoltaic devices respectively having a first principal surface on a side to which light mainly enters and a second principal surface on an opposite side to the side to which light mainly enters are arranged; a substrate that has optical transparency and is arranged on a light incident side with respect to the device array; a first sealing portion that has optical transparency and is arranged between the device array and the substrate; a rear-surface protective member that is arranged on an opposite side to the light incident side with respect to the device array; a second sealing portion that is arranged between the device array and the rear-surface protective member; and a light scattering portion that is arranged in a region corresponding to a gap between the photovoltaic devices in inside of at least one of the first sealing portion, the second sealing portion, the rear-surface protective member, and the substrate. The light scattering portion has wavelength selectivity such that an optical reflectivity is equal to or less than 15% over a wavelength region of 500 nanometers to 600 nanometers inclusive, and there is a region having an optical reflectivity larger than 15% in a wavelength region overlapping on an absorption wavelength range of the photovoltaic device in one of wavelength regions of equal to or less than 350 nanometers and equal to or larger than 700 nanometers, and total integrated scattering of the light scattering portion becomes equal to or larger than 50% in the wavelength region overlapping on the absorption wavelength range of equal to or less than 350 nanometers and equal to or larger than 700 nanometers.

A solar battery module according to a second aspect of the present invention includes: a device array in which a plurality of photovoltaic devices are arranged; a substrate that has optical transparency and is arranged on a side to which light mainly enters with respect to the device array; a first sealing portion that has optical transparency and is arranged between the device array and the substrate; a rear-surface protective member that is arranged on an opposite side to the side to which light mainly enters with respect to the device array; a second sealing portion that is arranged between the device array and the rear-surface protective member; and a light reflecting portion that is arranged in a region corresponding to a gap between the photovoltaic devices in inside of at least the first sealing portion, the second sealing material, the rear-surface protective member, and the substrate. The light scattering portion has wavelength selectivity such that an optical reflectivity is equal to or less than 15% over a wavelength region of 500 nanometers to 600 nanometers inclusive, and there is a region having an optical reflectivity larger than 15% in a wavelength region overlapping on an absorption wavelength range of the photovoltaic device in one of wavelength regions of equal to or less than 350 nanometers and equal to or larger than 700 nanometers. Additionally, total integrated scattering of the light reflecting portion becomes less than 50% in the wavelength region overlapping on the absorption wavelength range of the photovoltaic device in one of the wavelength regions of equal to or less than 350 nanometers and equal to or larger than 700 nanometers. More additionally, a surface on a light incident side in the light reflecting portion includes a plurality of slope faces respectively having a reflecting surface inclined with an angle equal to or larger than α, which satisfies

α=(arcsin(1/n))/2

with respect to a light receiving surface of the substrate, when a refractive index of a medium in contact with the light reflecting portion is designated as n.

A solar battery module according to a third aspect of the present invention includes: a device array in which a plurality of photovoltaic devices respectively having a first principal surface on a side to which light mainly enters and on which a metal electrode is arranged and a second principal surface on an opposite side to the side to which light mainly enters are arranged; a substrate that has optical transparency and is arranged on a light incident side with respect to the device array; a first sealing portion that has optical transparency and is arranged between the device array and the substrate; a rear-surface protective member that is arranged on an opposite side to the light incident side with respect to the device array; a second sealing portion that is arranged between the device array and the rear-surface protective member; and a light scattering portion that is arranged in a region covering the metal electrode on each of the first principal surface of the photovoltaic devices. The light scattering portion has wavelength selectivity such that an optical reflectivity is equal to or less than 15% over a wavelength region of 500 nanometers to 600 nanometers inclusive, and there is a region having an optical reflectivity larger than 15% in a wavelength region overlapping on an absorption wavelength range of the photovoltaic device in one of wavelength regions of equal to or less than 350 nanometers and equal to or larger than 700 nanometers, and total integrated scattering of the light scattering portion becomes equal to or larger than 50% in the wavelength region overlapping on the absorption wavelength range of the photovoltaic device in one of the wavelength regions of equal to or less than 350 nanometers and equal to or larger than 700 nanometers.

A solar battery module according to a fourth aspect of the present invention includes: a device array in which a plurality of photovoltaic devices are arranged; a substrate that has optical transparency and is arranged on a side to which light mainly enters with respect to the device array; a first sealing portion that has optical transparency and is arranged between the device array and the substrate; a rear-surface protective member that is arranged on an opposite side to the side to which light mainly enters with respect to the device array; a second sealing portion that is arranged between the device array and the rear-surface protective member; and a light reflecting portion that is arranged in a region covering the metal electrode on each of the first principal surface of the photovoltaic devices. The light reflecting portion has wavelength selectivity such that an optical reflectivity is equal to or less than 15% over a wavelength region of 500 nanometers to 600 nanometers inclusive, and there is a region having an optical reflectivity larger than 15% in a wavelength region overlapping on an absorption wavelength range of the photovoltaic device in one of wavelength regions of equal to or less than 350 nanometers and equal to or larger than 700 nanometers. Additionally, total integrated scattering of the light reflecting portion becomes less than 50% in the wavelength region overlapping on the absorption wavelength range of the photovoltaic device in one of the wavelength regions of equal to or less than 350 nanometers and equal to or larger than 700 nanometers. More additionally, a surface on a light incident side in the light reflecting portion includes a plurality of slope faces respectively having a reflecting surface inclined with an angle equal to or larger than α, which satisfies

α=(arcsin(1/n))/2

with respect to a light receiving surface of the substrate, when a refractive index of a medium in contact with the light reflecting portion is designated as n.

### Advantageous Effects of Invention

According to the present invention, among light incident on a region between a plurality of photovoltaic devices or a region covering a metal electrode on a first principal surface of a photovoltaic device, the majority of light in a visible region is absorbed by a light scattering portion or a light reflecting portion to express a black color tone, while light in a wavelength region other than the visible region is scattered by the light scattering portion or the light reflecting portion to re-enter into the photovoltaic devices, thereby enabling to improve the use efficiency of light. That is, power output of a solar battery module can be improved, and design characteristics of the solar battery module can be also improved.

### BRIEF DESCRIPTION OF DRAWINGS

FIG. 1-1 depicts a configuration of a solar battery module according to a first embodiment.

FIG. 1-2 depicts a configuration of the solar battery module according to the first embodiment.

FIG. 1-3 depicts a configuration of the solar battery module according to the first embodiment.

FIG. 1-4 depicts a configuration of a light reflecting body according to the first embodiment.

FIG. 2-1 depicts a manufacturing method of the solar battery module according to the first embodiment.

FIG. 2-2 depicts the manufacturing method of the solar battery module according to the first embodiment.

FIG. 2-3 depicts the manufacturing method of the solar battery module according to the first embodiment.

FIG. 3-1 depicts a configuration of a solar battery module according to a second embodiment.

FIG. 3-2 depicts a configuration of the solar battery module according to the second embodiment.

FIG. 4-1 depicts a manufacturing method of the solar battery module according to the second embodiment.

FIG. 4-2 depicts the manufacturing method of the solar battery module according to the second embodiment.

FIG. 4-3 depicts the manufacturing method of the solar battery module according to the second embodiment.

FIG. 4-4 depicts the manufacturing method of the solar battery module according to the second embodiment.

FIG. 5-1 depicts a configuration of a solar battery module according to a third embodiment.

FIG. 5-2 depicts a configuration of the solar battery module according to the third embodiment.

FIG. 5-3 depicts a configuration and a manufacturing method of the solar battery module according to the third embodiment.

FIG. 5-4 depicts a configuration and the manufacturing method of the solar battery module according to the third embodiment.

### DESCRIPTION OF EMBODIMENTS

Exemplary embodiments of a solar battery module according to the present invention will be explained below in detail with reference to the accompanying drawings. The present invention is not limited to the embodiments. In addition, in the drawings explained below, for easier understanding, scales of respective members may be different from those of actual products. The same holds true for relationships between the drawings.

### First Embodiment

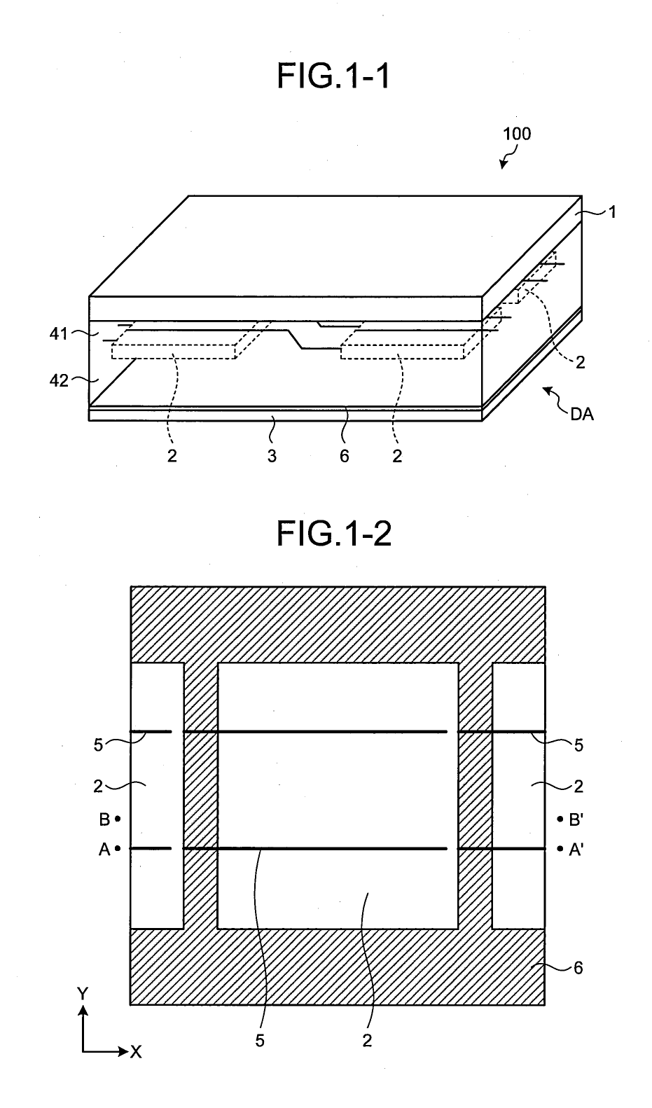

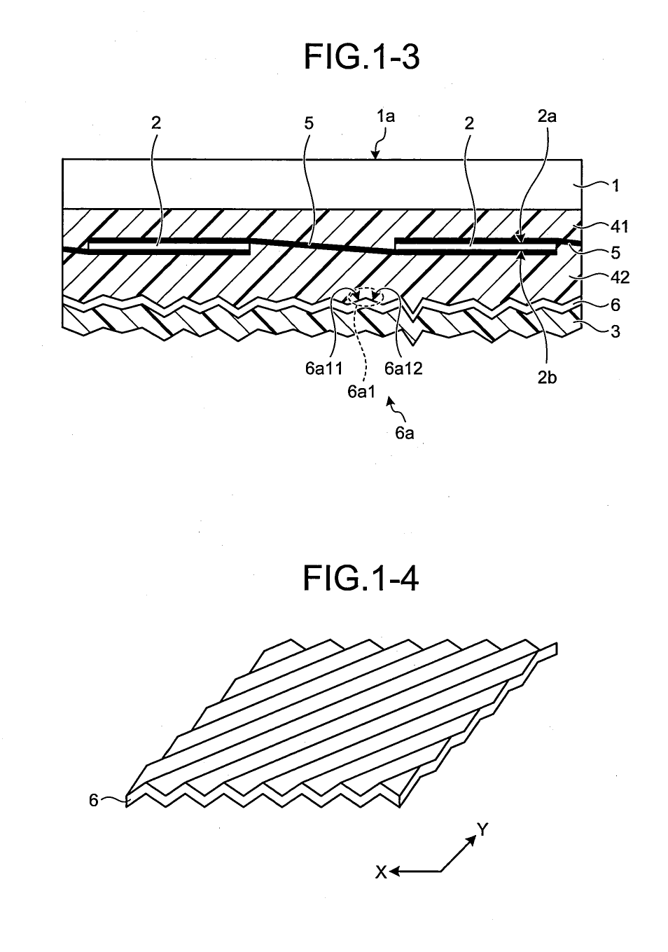

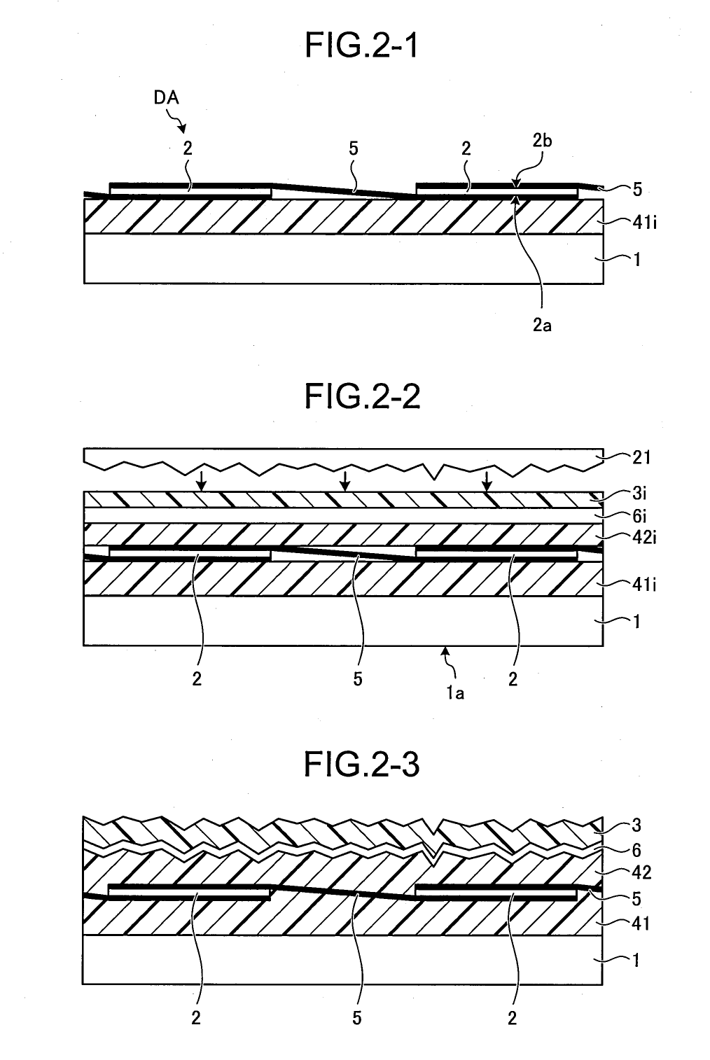

A configuration of a solar battery module 100 according to a first embodiment is explained with reference to FIGS. 1-1 to 1-4. FIG. 1-1 is a perspective view of relevant parts of the solar battery module 100. FIG. 1-2 is a plan view of the solar battery module 100 as viewed from a side of a light receiving surface 1a. FIG. 1-3 is a sectional view when the solar battery module 100 in FIG. 1-2 is cut by a segment connecting a point A and a point A′. FIG. 1-4 is a perspective view for explaining a configuration of a light reflecting body in the solar battery module 100.

The solar battery module 100 includes a device array DA, a transparent support body (substrate) 1, a weather-resistant polymeric film (rear-surface protective member) 3, a sealing resin (first sealing portion) 41, a sealing resin (second sealing portion) 42, an inter-element connecting line 5, and a black light reflecting body 6.

In the device array DA, a plurality of photovoltaic devices 2 are arranged substantially on one surface (for example, two-dimensionally) away from each other. The photovoltaic device 2 is formed of polycrystalline silicon, monocrystalline silicon, or a double-sided power generation type solar battery, for example. The photovoltaic device 2 absorbs light having a wavelength in an absorption wavelength range of the received light, and generates a charge-separated state (generates power) corresponding to the absorbed light.

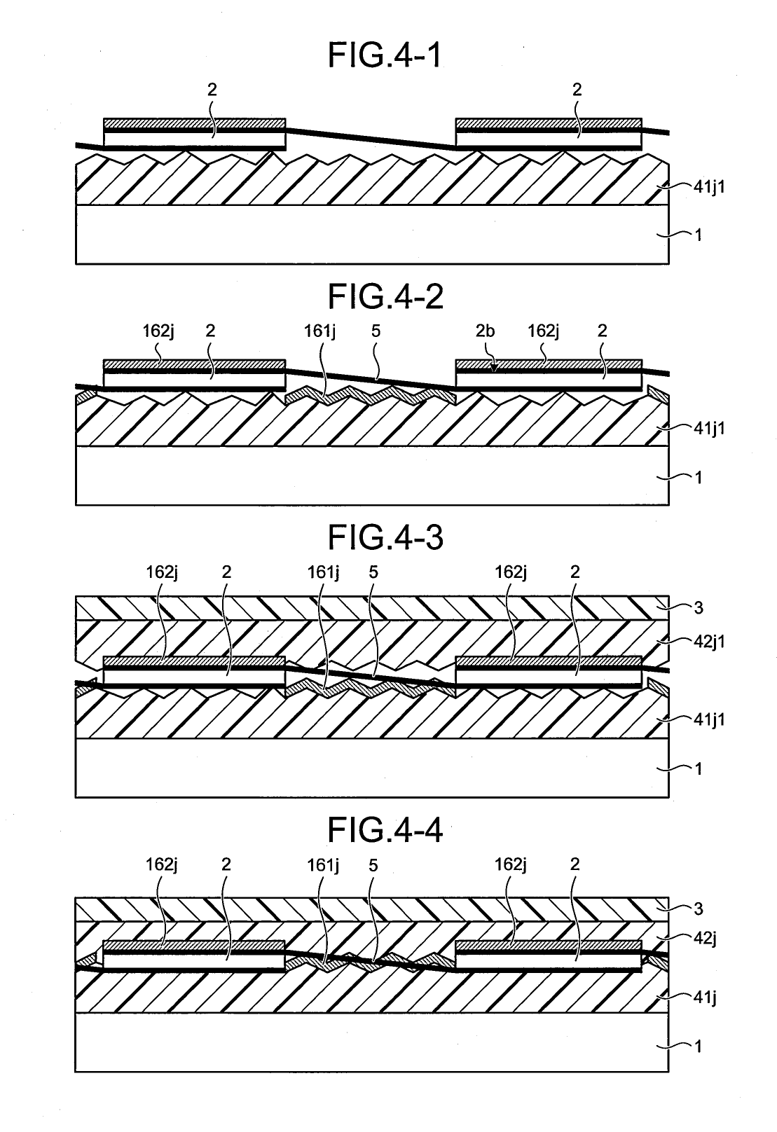

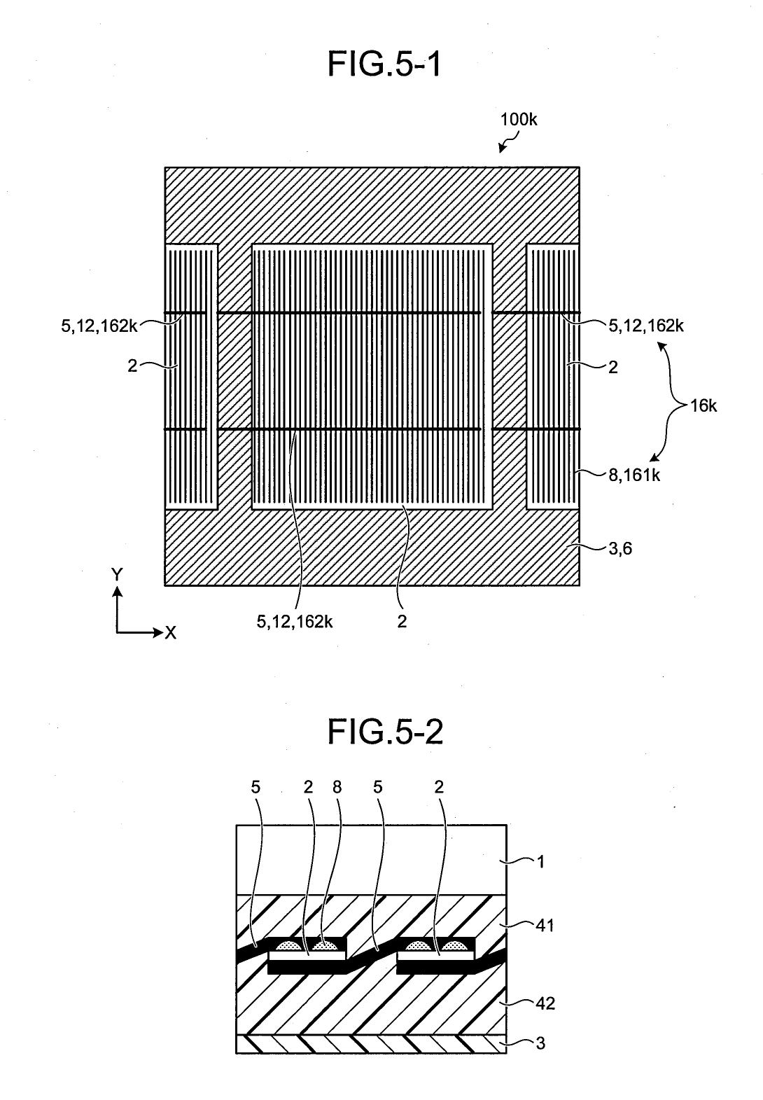

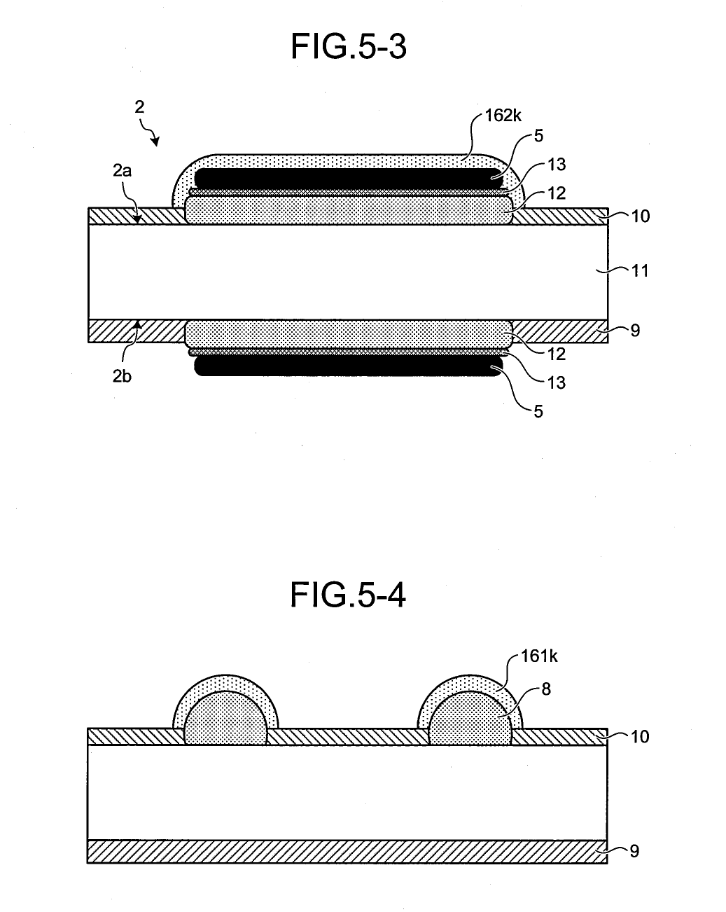

Each of the photovoltaic devices 2 includes a first principal surface 2a and a second principal surface 2b. A metal electrode (see a metal electrode 8 shown in FIG. 5-1) is arranged on the first principal surface 2a. The metal electrode includes a plurality of line patterns that respectively intersect the inter-element connecting line 5, for example. An electrode (see a rear-surface electrode 9 shown in FIG. 5-4) is arranged on the second principal surface 2b. For example, this electrode is formed to cover the second principal surface 2b. The electrode does not necessarily to cover the entire second principal surface 2b, and can be a solar battery cell that is present locally and can generate power on the both sides by light entering from the second principal surface 2b.

The transparent support body 1 is arranged on the light incident side with respect to the device array DA. The transparent support body 1 has optical transparency, and is formed of a material having the optical transparency such as transparent glass (for example, plate glass). In FIG. 1-2, the transparent support body 1 is not shown.

The weather-resistant polymeric film 3 is arranged on the opposite side to the light incident side with respect to the device array DA. For example, the weather-resistant polymeric film 3 is formed of a weather-resistant polyethylene terephthalate resin or a polyethylene terephthalate resin in which a white pigment is kneaded as a reflective material. It is not necessary that the protective member is an organic film, and can be glass having an irregular shape, for example.

The sealing resin 41 is arranged between the device array DA and the transparent support body 1. The sealing resin 42 is arranged between the device array DA and the weather-resistant polymeric film 3. The sealing resin 41 and the sealing resin 42 respectively have the optical transparency, and are formed of a transparent sealing material such as ethylene-vinyl acetate resin (EVA). In FIG. 1-2, the sealing resin 41 and the sealing resin 42 are not shown.

The inter-element connecting line 5 connects the metal electrode on the first principal surface 2a of a certain photovoltaic device 2 to the electrode on the second principal surface 2b of another photovoltaic device 2 adjacent to the photovoltaic device 2 (with a gap). For example, a copper wire is used for the inter-element connecting line 5. The inter-element connecting line 5 is soldered and connected to the metal electrode on the first principal surface 2a of the photovoltaic device 2, and is soldered and connected to the electrode on the second principal surface 2b of the adjacent photovoltaic device 2.

The black light reflecting body 6 is arranged on an interface between the weather-resistant polymeric film 3 and the sealing resin 42. The black light reflecting body 6 has wavelength selectivity such that an optical reflectivity is equal to or less than 15% over a wavelength region of 500 nanometers to 600 nanometers inclusive, and there is a region having an optical reflectivity larger than 15% in a wavelength region overlapping on an absorption wavelength range of the photovoltaic device 2 (crystalline silicon) in one of wavelength regions of equal to or less than 350 nanometers and equal to or larger than 700 nanometers. The black light reflecting body 6 is formed of an aluminum foil to which blackening processing (black alumite treatment) by anodization using perylene or the like is performed, for example, as a light reflecting body having such wavelength selectivity. Other than the aluminum foil, titanium can be also used for the black light reflecting body, whose surface is oxidized to a thickness of approximately 20 nanometers to 60 nanometers and displays blue due to interference of light, as shown in Japanese Patent Application Laid-open No. 2008-13833.

A case where the optical reflectivity is larger than 15% over the wavelength region of 500 nanometers to 600 nanometers inclusive is considered here. In this case, the black light reflecting body 6 has a tendency that it does not seem black. Accordingly, when the solar battery module 100 is observed from the side of the light receiving surface 1a of the transparent support body 1, the difference between the color tone of the black light reflecting body 6 and the color tone (black) of the photovoltaic device 2 becomes conspicuous.

On the other hand, according to the first embodiment, the optical reflectivity of the black light reflecting body 6 is equal to or less than 15% over the wavelength region of 500 nanometers to 600 nanometers inclusive. Accordingly, because the black light reflecting body 6 seems black, the difference between the color tone of the black light reflecting body 6 and the color tone (black) of the photovoltaic device 2 becomes inconspicuous.

A case where the optical reflectivity is equal to or less than 15% over the wavelength region overlapping on the absorption wavelength range of the photovoltaic device 2 in any of the wavelength regions of equal to or less than 350 nanometers and equal to or larger than 700 nanometers is considered here. In this case, intensity of light reflected by the black light reflecting body 6 is small, and is attenuated to a level at which light does not contribute to power output, before reaching the photovoltaic device 2. Accordingly, it is difficult to guide the light reflected by the black light reflecting body 6 to the photovoltaic devices 2.

On the other hand, according to the first embodiment, the black light reflecting body 6 has the region in which the optical reflectivity is larger than 15% in the wavelength region overlapping on the absorption wavelength range of the photovoltaic device 2 (crystalline silicon) in one of the wavelength regions of equal to or less than 350 nanometers and equal to or larger than 700 nanometers. Accordingly, the light reflected by the black light reflecting body 6 has sufficiently large intensity of light in a wavelength that is invisible for human eyes and a wavelength contributing to power generation, and by guiding the light to the photovoltaic devices 2, the light can contribute to power generation. That is, while the difference between the color tone of the black light reflecting body 6 and the color tone of the photovoltaic device 2 is made inconspicuous, the light reflected by the black light reflecting body 6 can be guided to the photovoltaic devices 2, thereby enabling to improve the power output of the solar battery module.

The black light reflecting body 6 can be formed of a coherent dielectric film. However, because the reflected wavelength is shifted according to an incident angle of light, the black light reflecting body 6 may not always appear black depending on the viewing angle.

Furthermore, the black light reflecting body 6 has total integrated scattering (TIS) of less than 50% (for example, equal to or less than 30%). The total integrated scattering here is a numerical value indicating the ratio of scattered light of reflected light, and is measured based on the method of American Society for Testing and Materials (ASTM) F1048-87 (1999).

It is desired that the total integrated scattering of the light reflecting body according to the present embodiment take a small value as much as possible in the wavelength region overlapping on the absorption wavelength range of the photovoltaic device in one of the wavelength regions of equal to or less than 350 nanometers and equal to or larger than 700 nanometers. Although being different depending on the module structure, when the total integrated scattering is large, light reflected by the reflecting body is scattered at the time of reflection, and the incident angle to an interface between the transparent support body 1 (glass) and the air does not become constant, and becomes smaller than a critical angle θ at which total reflection occurs. Furthermore, incident light components increase to cause the majority of light to penetrate the interface between the transparent support body 1 (glass) and the air, and light can be guided to the photovoltaic device only to the same level as that when the same reflecting body is used and a surface on which diffuse reflection (Lambert reflection) occurs is used.

Further, when it is difficult to measure a total integrated scattering value in each wavelength, approximate total integrated scattering in each wavelength can be estimated from a measurement value of a certain wavelength, by using a fact that total integrated scattering is inversely proportional approximately to a square of wavelength. Because total integrated scattering is approximately proportional to a square of a surface roughness (an arithmetic mean roughness of the surface) of a light reflecting layer, it is desired that the surface roughness be small so as to be used as the light reflecting body according to the first embodiment.

When a direction perpendicular to the light receiving surface 1a of the transparent support body 1 is assumed to be 0 degree, a condition that an incident angle of light reflected by the black light reflecting body 6 to the interface between the transparent support body 1 (glass) and the air becomes the critical angle θ is as shown by the following expression

sin θ=1/n (2)

when the refractive index of the sealing resin 42 (a medium in contact with the black light reflecting body 6) is designated as n. Therefore, a surface 6a on the light incident side of the black light reflecting body 6 includes a plurality of protrusions 6a1 respectively having reflecting surfaces 6a11 and 6a12 inclined with an angle equal to or larger than θ/2 with respect to the light receiving surface 1a of the transparent support body 1. That is, the surface 6a on the light incident side of the black light reflecting body 6 includes a plurality of protrusions 6a1 respectively having reflecting surfaces 6a11 and 6a12 inclined with an angle equal to or larger than α satisfying

α=(arcsin(1/n))/2 (3)

with respect to the light receiving surface 1a of the transparent support body 1.

A case where the total integrated scattering of the black light reflecting body 6 is larger than 50% is considered here. In this case, because specular reflection of light reflected by a reflecting surface of the black light reflecting body 6 is low, even if the reflecting surface of the black light reflecting body 6 satisfies the expression (2) or (3), the incident angle of light reflected by the black light reflecting body 6 to the transparent support body 1 (glass) becomes smaller than the critical angle θ, and thus there is a high possibility that the light is not reflected but is refracted, and penetrates the transparent support body 1. Accordingly, it becomes difficult to guide the light reflected by the black light reflecting body 6 to the photovoltaic devices 2. Furthermore, when a reflecting body in which a scattering body close to a complete diffuser generally used heretofore is embedded in a medium having a refractive index of 1.5 is used, the incident angle to the transparent support body 1 (glass) becomes smaller than the critical angle θ in about half of the light reflected by a scattering reflecting body and light penetrates the transparent support body 1, although the degree is different depending on the refractive index of the medium constituting the module, surface smoothness of the transparent support body, and the gap between the photovoltaic devices. Therefore, there is a problem that the use efficiency of light is low.

On the other hand, according to the first embodiment, because the total integrated scattering is less than 50%, specular reflection of light reflected by the reflecting surfaces 6a11 and 6a12 of the black light reflecting body 6 becomes high. Accordingly, if an angle of inclination of the reflecting surfaces 6a11 and 6a12 of the black light reflecting body 6 has a value equal to or larger than α, which satisfies the expression (3), the incident angle of the light reflected by the black light reflecting body 6 to the transparent support body 1 (glass) becomes larger than the critical angle θ, and the light reflected by the black light reflecting body 6 can be totally reflected easily. Consequently, the light reflected by the black light reflecting body 6 can be efficiently guided to the photovoltaic devices 2.

Furthermore, a case where the angle of inclination of the reflecting surface of the black light reflecting body 6 has a value smaller than α, which satisfies the expression (3), is considered here. In this case, even if the specular reflection of light reflected by the reflecting surface of the black light reflecting body 6 becomes high, the incident angle of the light reflected by the black light reflecting body 6 to the transparent support body 1 (glass) becomes smaller than the critical angle θ. Therefore, there is a high possibility that the light is not reflected but is refracted, and penetrates the transparent support body 1. Accordingly, it becomes difficult to guide the light reflected by the black light reflecting body 6 to the photovoltaic devices 2.

On the other hand, according to the first embodiment, the surface 6a on the light incident side of the black light reflecting body 6 includes the plurality of protrusions 6a1 respectively having the reflecting surfaces 6a11 and 6a12 inclined with the angle equal to or larger than α satisfying the expression (3) with respect to the light receiving surface 1a of the transparent support body 1. Accordingly, if specular reflection of light reflected by the reflecting surfaces 6a11 and 6a12 of the black light reflecting body 6 becomes high, the incident angle of the light reflected by the black light reflecting body 6 to the transparent support body 1 (glass) becomes larger than the critical angle θ, and the light reflected by the black light reflecting body 6 can be totally reflected easily. Consequently, the light reflected by the black light reflecting body 6 can be efficiently guided to the photovoltaic devices 2.

For example, the specific shape of the black light reflecting body 6 is a shape as shown in FIG. 1-4. That is, the surface 6a on the light incident side of the black light reflecting body 6 is formed to be a plane on which triangular prisms are repeatedly arranged horizontally. As an example in which the direction in which the triangular prisms are extended is angled with respect to an end of the solar battery module 100, a case of a light reflecting body in which a line of intersection between a plane parallel to a slope face (a light reflecting surface) of the black light reflecting body 6 and the surface (the light receiving surface 1a) of the solar battery module 100 is arranged at 45 degrees is shown in FIGS. 1-2 to 1-4. In FIGS. 1-2 to 1-4, the black light reflecting body 6 has a surface structure having a shape formed by laying the triangular prisms horizontally, and a ridge line of the triangular prism (parallel to the line of intersection between a plane parallel to the slope face (the light reflecting surface) of the black light reflecting body 6 and the surface (the light receiving surface 1a) of the solar battery module 100) is arranged with an angle of 45 degrees with respect to a vertical side (in a Y direction in FIGS. 1-2 and 1-4) or on a horizontal side (in an X direction in FIG. 1-2) of a grid formed by the gaps between the photovoltaic devices adjacent to each other in an in-plane direction.

Alternatively, for example, although not shown in the drawings, the specific shape of the black light reflecting body 6 can be a shape where a plurality of pyramid protrusions are provided on the surface 6a on the light incident side.

The black light reflecting body 6 arranged in this manner is a light reflecting body having a shape excellent in mass productivity. Therefore, the black light reflecting body 6 itself has excellent mass productivity, and at the time of manufacturing the solar battery module 100 by using the black light reflecting body 6, any alignment is not required, and thus the solar battery module 100 having excellent mass productivity and an increased amount of light to be guided to each cell (each photovoltaic device 2) can be manufactured.

That is, among light incident on the surface on the light incident side (the light receiving surface 1a) of the solar battery module 100, having passed between the photovoltaic devices adjacent to each other and reached the surface opposite to the light incident side of the solar battery module 100, a part of light in a wavelength region other than the visible light is reflected by the black light reflecting body 6. The light reflected by the black light reflecting body 6 is further reflected by the interface between the air and the solar battery module 100, and is guided to the photovoltaic devices 2.

For example, when the sealing resin 42 of the solar battery module 100 is formed of general EVA resin, because the refractive index of the EVA resin is approximately 1.5, the critical angle becomes approximately 42 degrees based on the expression (2). For efficient light guiding, the angle formed between the slope face of the black light reflecting body 6 and the light receiving surface 1a of the transparent support body 1 needs to be equal to or larger than 21 degrees based on the expression (3).

Furthermore, reflected light by the black light reflecting body 6 having an angle equal to or larger than a shown in the expression (3) with respect to the light receiving surface 1a is reflected by the interface between the transparent support body 1 (glass) and the air, and is guided in a direction parallel to the light receiving surface 1a. As the angle between the light receiving surface 1a of the solar battery module 100 and the slope face (the light reflecting surface) of the black light reflecting body 6 increases, light has an angle in the direction parallel to the light receiving surface 1a, and thus a light guiding distance increases and light can be easily guided to the photovoltaic devices 2. On the other hand, if the angle between the light receiving surface 1a of the solar battery module 100 and the slope face (the light reflecting surface) of the black light reflecting body 6 increases excessively (for example, equal to or larger than 2a), light is multiply-reflected between adjacent slope faces (light reflecting surfaces) of the black light reflecting body 6, thereby increasing the incident angle θ of reflected light of the black light reflecting body 6 to the interface between the glass and the air. Accordingly, reflected light is emitted from the glass and light guiding efficiency deteriorates.

Therefore, for example, by setting so that the black light reflecting body 6 forms an angle of approximately 30 degrees (≧21 degrees<42 degrees) with respect to the light receiving surface 1a, the light guiding distance of light in a wavelength region other than the visible light, among light incident on the light receiving surface 1a of the solar battery module 100, in the direction parallel to the light receiving surface 1a increases, and particularly the power output can be improved.

As described above, in the solar battery module 100 according to the first embodiment, the black light reflecting body 6 formed of an alumite-treated aluminum foil and having an optical reflectivity (having wavelength selectivity) with respect to the light in the wavelength region other than the visible light, among the light incident on the surface of the solar battery module 100, is provided in the interface between the weather-resistant polymeric film 3 and the sealing resin 42 in the solar battery module 100. The black light reflecting body 6 is mainly formed of slope faces (light reflecting surfaces) forming the angle equal to or larger than α satisfying the expression (3) mentioned above with respect to the light receiving surface 1a of the solar battery module 100. For example, the surface shape thereof can be a shape in which the triangular prisms are arranged in parallel (prisms are arranged in parallel). As the shape of the triangular prism, examples are mentioned in Japanese Patent No. 3616568 and Japanese Patent No. 3433224.

Accordingly, light having entered into the light receiving surface 1a of the solar battery module 100 and having passed through a region between the adjacent photovoltaic devices 2 (a non-power generation region) is reflected by the black light reflecting body 6, so as to enter into the light receiving surface 1a of the solar battery module 100 with an angle larger than the critical angle of the interface between the solar battery module and the air. The reflected light can be totally reflected by the interface between the solar battery module and the air. That is, the light having passed through the region between the adjacent photovoltaic devices 2 (the non-power generation region) can be effectively guided to the photovoltaic devices 2.

Therefore, according to the first embodiment, in the solar battery module 100, because total integrated scattering is low and specular reflection is high, light in the wavelength region other than the visible light, which has passed through the region between the adjacent photovoltaic devices 2, can be caused to re-enter into the photovoltaic devices 2 efficiently to increase the use efficiency of light, thereby enabling to improve the power output. Simultaneously, by absorbing the visible light and unifying the color tone of the photovoltaic devices and the gap therebetween, the solar battery module 100 having high design characteristics is realized. That is, the power output of the solar battery module 100 can be improved and the design characteristics of the solar battery module 100 can be improved.

Furthermore, in the solar battery module 100 according to the first embodiment, because a metal film (for example, as described above, an aluminum film, which is a left portion of an aluminum foil that is not anodized) is used as a part of the black light reflecting body, the metal film can prevent moisture from penetrating into a solar power element from outside of the solar battery module 100. Accordingly, the solar battery module 100 having high reliability is realized.

According to the first embodiment, the black light reflecting body 6 having an uneven structure is used as the black light reflecting body provided in contact with the weather-resistant polymeric film (rear-surface protective member) 3. However, instead of the black light reflecting body, a black light scattering material can be used. In this case, light incident on the black light scattering material is scattered in various directions, and the incident angle to the transparent support body 1 (glass) easily becomes larger than the critical angle θ, and the light is totally reflected on the interface between the glass and the air. Accordingly, light can be guided to the photovoltaic devices 2 to contribute to power generation, and the appearance thereof can have uniformity. In this case, it is not always necessary that the black scattering body has irregularities. Therefore, in the solar battery module 100, the majority of light in the visible region, among the light incident on the non-power generation region, is absorbed by the light scattering portion to express black color, while light in the wavelength region other than the visible region is scattered by the light scattering portion, and is caused to re-enter into the photovoltaic devices 2, thereby enabling to improve the use efficiency of light. That is, the power output of the solar battery module 100 can be improved, and the design characteristics of the solar battery module 100 can be improved.

Further, in the present embodiment, a solar battery cell having an electrode on both two principal surfaces is used. However, a back contact cell can be used, in which there is no electrode on the principal surface as the main light receiving surface, and an electrode is arranged only on the principal surface on the opposite side.

A manufacturing method of the solar battery module 100 according to the first embodiment is explained with reference to FIGS. 2-1 to 2-3, by using a monocrystalline silicon solar battery module that uses a monocrystalline silicon solar battery cell (hereinafter, “cell 2”) as the photovoltaic device 2 as an example. FIGS. 2-1 to 2-3 are sectional views for explaining the manufacturing method of the solar battery module 100 according to the first embodiment.

In the process shown in FIG. 2-1, a conductive wire as the inter-element connecting line 5 is spanned over between an electrode on the light incident side of one cell 2, among two cells 2, and an electrode on the opposite side to the light incident side of the other cell 2 (between a negative electrode and a positive electrode), and the respective electrodes and the conductive wire are soldered, thereby electrically connecting one of the cells 2 and the other cell 2. A plurality of cells 2 are electrically connected in this manner to serially connect all the cells 2, and the cells 2 are beaded in a line to connect each other in one line.

Next (in an arranging process), a sheet-like sealing resin 41i is placed on the transparent support body 1 (for example, a transparent glass substrate). The sealing resin 41i is formed of ethylene-vinyl acetate resin (EVA), for example. The lined cells 2 (in the device array DA) are placed, with the first principal surface 2a thereof being on a side of the transparent support body 1 (the light incident side) and the second principal surface 2b being on the opposite side to the transparent support body 1.

In the process shown in FIG. 2-2 (in an arranging process), a sheet-like sealing resin 42i is placed on the cells 2. For example, the sealing resin 42i is formed of ethylene-vinyl acetate resin (EVA), for example. A weather-resistant polyethylene terephthalate film is used as a weather-resistant polymeric film 3i and an aluminum foil is bonded to the surface thereof as a black light reflecting body 6i. Black alumite treatment is applied to the aluminum foil by anodization using perylene or the like, so that the surface of the aluminum foil becomes black, thereby forming the weather-resistant polymeric film 3i to which the black light reflecting body 6i is bonded. The weather-resistant polymeric film 3i is placed on the sealing resin 42i so that the black light reflecting body 6i is on the side of the light receiving surface 1a (EVA side).

As described above, the transparent support body 1, the sealing resin 41i, the device array DA, the sealing resin 42i, and the weather-resistant polymeric film 3i are sequentially laminated and arranged.

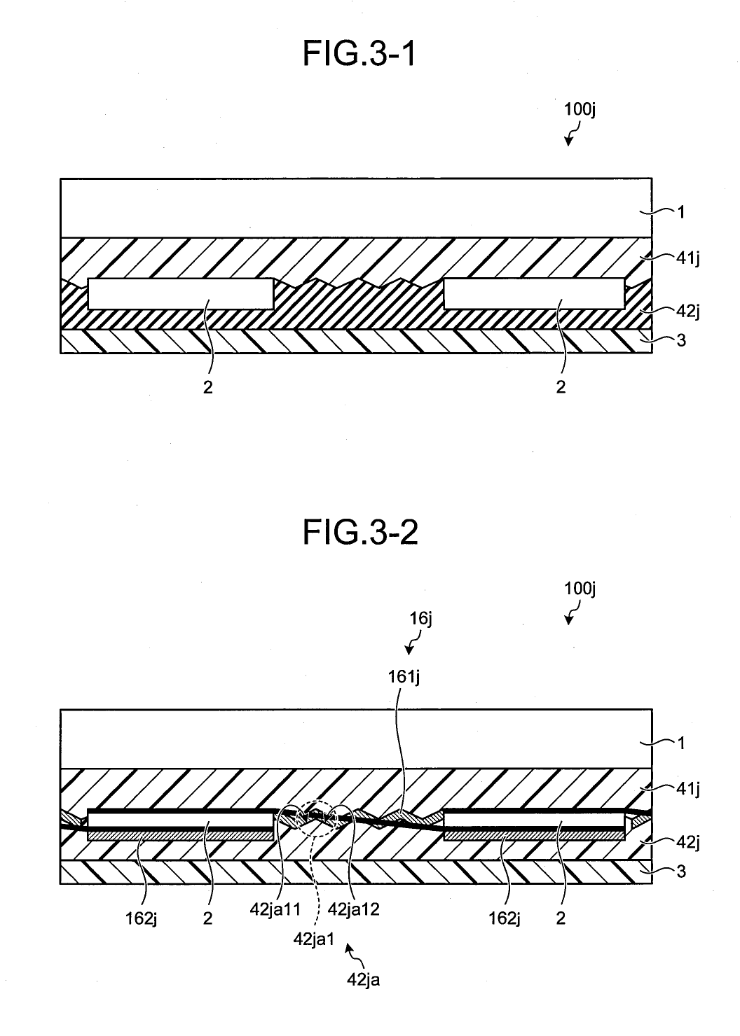

In the process shown in FIG. 2-3 (a sealing process), the device array DA is sealed by a sealing material (the sealing resin 41i and sealing resin 42i) between the transparent support body 1 and the weather-resistant polymeric film 3. At this time, the black light reflecting body 6i is pressure-molded so that the surface 6a on the light incident side of the black light reflecting body 6 includes a plurality of protrusions 6a1, respectively having the reflecting surfaces 6a11 and 6a12 inclined with an angle equal to or larger than α satisfying the expression (3). That is, in order to form irregularities on the black light reflecting body 6i, a hard plate having irregularities, for example, irregularities corresponding to a shape shown in FIG. 1-4, or a mold 21 having pyramid irregularities of approximately 50 micrometers is laid on the top of the black light reflecting body 6i. The slope face in each pyramid protrusion is formed to have the angle equal to or larger than α satisfying the expression (3) with respect to the light receiving surface 1a of the transparent support body 1 (the transparent glass substrate).

The entire laminated body in which the transparent support body 1, the sealing resin 41i, the device array DA, the sealing resin 42i, and the weather-resistant polymeric film 3i are sequentially laminated is put between diaphragms. The laminated body is heated to a temperature equal to or higher than a softening temperature of the sealing material (the sealing resin 41i and the sealing resin 42i) under a reduced pressure, thereby softening the sealing material. A pressure is applied between the transparent support body 1 (the transparent glass substrate) and the sealing resin 41i and the sealing resin 42i (two weather-resistant polyethylene terephthalate films) to apply pressure bonding on the sealing resin 41i and the sealing resin 42i (the EVA sheets) (FIG. 2-3). Accordingly, the solar battery module 100 is formed.

As described above, in the manufacturing method of the solar battery module 100 according to the first embodiment, the black light reflecting body 6 having wavelength selectivity is formed between the weather-resistant polymeric film 3 and the sealing resin 42 on a rear surface of the solar battery module 100. The black light reflecting body 6i is pressure-molded so that the surface 6a on the light incident side of the black light reflecting body 6 includes a plurality of protrusions 6al, respectively having the reflecting surfaces 6a11 and 6a12 inclined with the angle equal to or larger than α satisfying the expression (3) with respect to the light receiving surface 1a of the transparent support body 1. Accordingly, light having a wavelength other than the visible light, among light incident on the region between the adjacent photovoltaic devices (the non-power generation region), is reflected by the black light reflecting body 6 so as to be incident on the light receiving surface 1a of the transparent support body 1 with an angle larger than the critical angle of the interface between the solar battery module and the air. As a result, the reflected light can be totally reflected by the interface between the solar battery module and the air.

Therefore, according to the manufacturing method of the solar battery module 100 according to the first embodiment, light incident on the non-power generation region of the solar battery module 100 can be caused to re-enter into the photovoltaic devices 2 to increase the use efficiency of light, thereby enabling to increase the power output and to manufacture the solar battery module 100 having excellent design characteristics.

Furthermore, according to the manufacturing method of the solar battery module 100 according to the first embodiment, because the metal film (the aluminum film, which is a left portion of an aluminum foil that is not anodized) prevents moisture, salt, and the like from penetrating from outside of the module into the outside of the module, the solar battery module 100 having high reliability can be manufactured.

Therefore, according to the manufacturing method of the solar battery module 100 according to the first embodiment, light incident on the non-power generation region where there is no photovoltaic device 2 can be guided to the photovoltaic devices 2. The difference in color tone between the gap between the photovoltaic devices and the photovoltaic device itself, or between the surface and the rear surface of the photovoltaic device is reduced, and thus the solar battery module 100 having high reliability and high design characteristics, and having excellent power output can be manufactured.

The photovoltaic device 2 can be a double-sided power generation element. In this case, because the black light reflecting body 6 is arranged on a side of the second principal surface 2b (on the side having a lower power generation efficiency) of the photovoltaic device 2, light having entered from the first principal surface 2a of the photovoltaic device 2 and coming out from the second principal surface 2b of the photovoltaic device 2 can be reflected by the black light reflecting body 6 and guided to the photovoltaic devices 2 again. Accordingly, light can re-enter into the photovoltaic devices 2 and contribute to power generation, and thus the solar battery module 100 including the photovoltaic devices 2 having excellent power output can be acquired. At this time, when a see-through solar battery module 100 that can introduce light in the outdoor area by covering the entire rear surface of the solar battery module 100 with a transparent material (by forming the weather-resistant polymeric film 3 by a light transmissive material) is produced, the appearance on the side of the second principal surface 2b and the appearance on the side of the first principal surface 2a of the photovoltaic device 2 become the same. Accordingly, the solar battery module 100 having excellent design characteristics can be acquired.

When the photovoltaic device 2 is formed as a double-sided power generation element, the surface on the light incident side of the black light reflecting body 6 can have a different inclination angle formed between the light reflecting surface and the light receiving surface 1a of the transparent support body 1, in a region corresponding to the photovoltaic device 2 and in a region corresponding to the gap between the adjacent photovoltaic devices 2. That is, the black light reflecting body 6 has a first light reflecting region positioned between the photovoltaic devices as viewed from a direction perpendicular to the light receiving surface 1a of the transparent support body 1 and a second light reflecting region overlapping on the photovoltaic device 2 as viewed from the direction perpendicular to the light receiving surface 1a of the transparent support body 1. The first light reflecting region includes the protrusions 6a1 described above. The second light reflecting region includes a plurality of second protrusions respectively having a reflecting surface inclined with an angle smaller than α satisfying the expression (3) with respect to the light receiving surface 1a of the transparent support body 1. As the angle incident on the side of the second principal surface 2b of the photovoltaic device 2, among light reflected by the second light reflecting region, becomes approximately vertical, the optical reflectivity on the second principal surface 2b of the photovoltaic device 2 is reduced, thereby increasing the power generation efficiency. Therefore, it is preferable that there is no protrusion as the second light reflecting region. Further, in the manufacturing method of the solar battery module 100, the mold 21 used in the process shown in FIG. 2-2 is formed beforehand in a shape corresponding to such a shape. Accordingly, light having penetrated the photovoltaic devices 2 is reflected by the second light reflecting region of the black light reflecting body 6 so as to re-enter into the photovoltaic devices 2. Simultaneously, light having penetrated the gap between the adjacent photovoltaic devices is reflected by the first light reflecting region of the black light reflecting body 6 so as to re-enter into the photovoltaic devices 2. As a result, the power generation efficiency of the solar battery module 100 can be further improved.

The black light reflecting body 6 can be a flat shape; however, the black light reflecting body 6 can be formed of a light reflecting surface having an angle equal to or larger than α satisfying the expression (3) with respect to the light receiving surface 1a of the transparent support body 1. A manufacturing method favorable to the power output can be selected depending on the gap between the adjacent photovoltaic devices. For example, in the case of a thin-film solar battery using a transparent glass electrode, represented by an amorphous silicon solar battery, the gap between the adjacent photovoltaic devices is as narrow as equal to or less than 1 millimeter, and thus a gain obtained by reflecting light entering in between the adjacent photovoltaic devices and guiding the light to the photovoltaic devices is not so large. Therefore, in this case, the black light reflecting body 6 can be formed in a planar form over the surface (the rear surface) on the opposite side to the light incident side of the solar battery module 100.

Furthermore, the black light reflecting body 6 can be formed of a material including as a main component of at least one substance selected from a group consisting of tin, nickel, aluminum, zinc, titanium, copper, and silver. That is, the black light reflecting body 6 can be formed in such a manner that at least one surface of at least one substance (one type of metal or an alloy of plural types of metal) selected from the group consisting of tin, nickel, aluminum, zinc, titanium, copper, and silver is oxidized (anodized).

### Second Embodiment

A solar battery module 100j according to a second embodiment is explained next with reference to FIG. 3. FIG. 3-1 is a sectional view of a configuration example of the solar battery module 100j according to the second embodiment, when the solar battery module 100 in FIG. 1-2 is cut by a segment connecting a point B and a point B′. FIG. 3-2 is a sectional view of another configuration example of the solar battery module 100j according to the second embodiment, when the solar battery module 100 in FIG. 1-2 is cut by a segment connecting the point A and the point A′. In the following descriptions, elements different from those of the first embodiment are mainly explained.

The solar battery module 100j includes a sealing resin 41j and a sealing resin 42j.

The sealing resin 42j functions as a black scattering portion. That is, the sealing resin 42j is formed of ethylene-vinyl acetate resin (EVA) in which a Black 411A pigment or a Brown 10C873 pigment manufactured by Shepherd Color Company is kneaded, for example. In the sealing resin 42j, it is desired that light scattering be high in order to totally reflect light in the interface between the air and the glass 1 effectively, and it is desired that total integrated scattering is equal to or larger than 50%.

The sealing resin 42j is formed by kneading the Black 411A pigment or the Brown 10C873 pigment manufactured by Shepherd Color Company, for example, as a resin having such wavelength selectivity. Because the optical reflectivity of the general crystalline silicon solar battery cell with an antireflective film in the wavelength region of 500 nanometers to 600 nanometers is less than approximately 10%, and the optical reflectivity thereof in the wavelength region around 400 nanometers is less than approximately 30%, the optical reflectivity of the scattering body in the wavelength region of 400 nanometers to 600 nanometers needs to be suppressed to less than approximately 30% in order to match the color tone in the appearance of the crystalline silicon solar battery cell and the scattering body. Therefore, the reflectivity needs to be less than approximately 15% in the wavelength range from 500 nanometers to 600 nanometers, and it is desired to be less than approximately 10%. It is not always necessary that the sealing resin 42j has a low optical reflectivity at all wavelengths in the visible region, and the color of the sealing resin 42j can be selected to match the color tone of the photovoltaic device 2. For example, for the crystalline silicon solar battery in which it is difficult to form an uneven structure on the surface thereof and the color after forming the antireflective film often seems blue, a Blue 30C588 pigment manufactured by Shepherd Color Company or a blue or purple pigment such as Ultramarine Deep, which is a color material manufactured by HOLBEIN WORKS, LTD., or a mixture thereof can be used as an additive to the sealing resin 42j in order to be matched with the color tone of the crystalline silicon solar battery. In this manner, when the scattering body expresses blue color, the optical reflectivity of the wavelength region around 400 nanometers can be high. On the other hand, the optical reflectivity in the wavelength region of approximately 500 nanometers to 600 nanometers needs to be set to be equal to or less than 15%. Because the optical reflectivity of the general crystalline silicon solar battery cell with the antireflective film in the wavelength region of 500 nanometers to 600 nanometers is equal to or less than 10%, it is desired that the reflectivity be less than approximately 10% in the wavelength region of approximately 500 nanometers to 600 nanometers in order to match the color tone with the crystalline silicon solar battery cell.

When the concentration of the pigment contained in the sealing resin 42j is low, and the optical reflectivity is not sufficiently high, a light scattering portion 16j can be added as shown in FIG. 3-2. At this time, the light scattering portion 16j has a plurality of black scattering bodies (a plurality of first scattering bodies) 161j, and a plurality of black scattering bodies (a plurality of second scattering bodies) 162j. The black scattering bodies 161j and 162j respectively have wavelength selectivity such that the optical reflectivity is equal to or less than 15% over the wavelength region of 500 nanometers to 600 nanometers inclusive, and there is a region having an optical reflectivity larger than 15% in the wavelength region overlapping on the absorption wavelength range of the photovoltaic device 2 (crystalline silicon) in one of wavelength regions of equal to or less than 350 nanometers and equal to or larger than 700 nanometers. The black scattering bodies 161j and the black scattering bodies 162j are respectively formed of, for example, the Black 411A pigment or the Brown 10C873 pigment manufactured by Shepherd Color Company, as that having such wavelength selectivity. The optical reflectivity of the black scattering bodies 161j and 162j does not need to be necessarily low at all wavelengths of the visible region, and a color matched with the color tone of the photovoltaic device 2 can be selected. For example, for the crystalline silicon solar battery in which it is difficult to form an uneven structure on the surface thereof and the color after forming the antireflective film often seems blue, the Blue 30C588 pigment manufactured by Shepherd Color Company or a blue or purple pigment such as Ultramarine Deep, which is a color material manufactured by HOLBEIN WORKS, Ltd, or a mixture thereof can be used as the black scattering bodies 161j and 162j in order to be matched with the color tone of the crystalline silicon solar battery.

The black scattering bodies 161j are arranged between the photovoltaic devices 2 in the interface between the sealing resin 41j and the sealing resin 42j. The black scattering bodies 162j cover the respective second principal surfaces 2b of the photovoltaic devices 2. Titania particles having a high light scattering property can be mixed with the pigment so that light intensity reflected from the black scattering bodies 161j becomes high and light intensity at which the incident angle θ of light to the glass becomes larger than the angle (the critical angle) satisfying the condition of the expression (3) becomes high.

The light scattering portion 16j can be a light reflecting body. In this case, a surface 42ja on the light incident side includes a plurality of protrusions 42ja1 respectively having reflecting surfaces 42ja11 and 42ja12 inclined with the angle α or larger, which satisfies the expression (3), with respect to the light receiving surface 1a of the transparent support body 1. Accordingly, the same material as that of the black light reflecting body 6 can be used for the reflecting surface, correspondingly.

A common feature between the configuration example shown in FIG. 3-1 and the configuration example shown in FIG. 3-2 is explained below.

The thickness of the photovoltaic device 2 is approximately 300 nanometers to 500 micrometers, and the thickness of the sealing resins 41j and 42j that seal the photovoltaic devices 2 is approximately 100 micrometers to several millimeters. At this time, the thicknesses of the black scattering bodies 161j and 162j have a size that can be fitted in the sealing resins 41j and 42j, and are several micrometers to several hundreds micrometers. The thicknesses of the black scattering bodies 161j and 162j can be appropriately changed, while matching the configuration of the solar battery module 100j.

The total integrated scattering of the scattering body used in the sealing resin 42j and the black scattering bodies 161j and 162j are preferably larger than approximately 50%.

More specifically, it is desired that the incident light components, which becomes equal to or lower than 0 in the expression (2), of a spectral reflectance factor or BRDF (Bidirectional Reflection Distribution Function) account for the largest portion of the total reflected light. The spectral reflectance factor is defined in JIS Z8722, and the BRDF can be measured by ASTME 1392-90 and JIS Z8528-2 Annex C, 2006 as a reference.

When the total integrated scattering is small, the majority of light reflected from the scattering body is specularly reflected without being scattered, the incident angle thereof to the transparent support body 1 (glass) becomes smaller than the critical angle θ, and the light penetrates to the air and is not guided to the photovoltaic devices, and thus the use efficiency of light becomes low.

Generally, because the total integrated scattering (TIS) is approximately proportional to the square of a surface roughness (an arithmetic mean roughness of the surface) of the light reflecting layer, and is inversely proportional to the square of the wavelength, as in the following expression (4), it is preferred that the surface roughness be from 10 nanometers to 10 micrometers, and more preferably, from 0.1 micrometer to 1 micrometer so as to be used as the light reflecting body in the intended wavelength.

TIS=1−exp{(−4πσ/λ)²}≅(4πσ/λ)² (4)

where σ denotes a square mean roughness of the surface of the light scattering body, and λ denotes the wavelength of light.

It is desired that the total integrated scattering satisfies the above range in the wavelength region overlapping on the absorption wavelength range of the photovoltaic device in one of wavelength regions of equal to or less than 350 nanometers and equal to or larger than 700 nanometers. However, when it is difficult to measure the value in each wavelength, approximate total integrated scattering in each wavelength can be estimated from a measurement value of a certain wavelength, by using the fact that the total integrated scattering is approximately inversely proportional to the square of the wavelength.

Accordingly, when the light scattering body used in the sealing resin 42j and the black scattering bodies 161j and 162j are made of particles, it is desired that respective particles have a diameter of 100 nanometers to 10 micrometers inclusive.

A case where particles in each of the black scattering body in the sealing resin 42j and the black scattering bodies 161j and 162j have a particle diameter smaller than 100 nanometers is considered here. In this case, because strong light scattering does not occur, there is such a tendency that the incident angle of light reflected from the black light reflecting body 6 to the transparent support body 1 (glass) becomes smaller than the critical angle θ and the light is not reflected but is refracted. Therefore, it is difficult to guide the light having entered into the black scattering bodies 161j and 162j to the photovoltaic devices 2.

Alternatively, a case where the particle diameter of particles in each of the black scattering body in the sealing resin 42j and the black scattering bodies 161j and 162j is larger than 10 micrometers is considered here. In this case, because scattering intensity of light per volume is weak, there is such a tendency that the incident angle of light reflected from the black light reflecting body 6 to the transparent support body 1 (glass) becomes smaller than the critical angle θ and the light penetrates without being reflected. Therefore, it is difficult to guide the light having entered into the black scattering bodies 161j and 162j to the photovoltaic devices 2.

On the other hand, according to the second embodiment, the particle diameter of particles in each of the black scattering body in the sealing resin 42j and the black scattering bodies 161j and 162j is larger than hundred nanometers, at which strong light scattering occurs with respect to light in a wavelength region having a large amount of sunlight, and are less than approximately several tens of micrometers, at which scattering intensity of light per volume is sufficiently large. Accordingly, because the light having entered into the black scattering body 161j in an area between the photovoltaic devices 2 is scattered in various directions, the incident angle of light scattered by the black scattering body in the sealing resin 42j or the black scattering body 161j to the transparent support body 1 (glass) becomes larger than the critical angle θ easily, and the light scattered by the sealing resin 42j or the black scattering body 161j can be totally reflected easily. Accordingly, the light scattered by the sealing resin 42j or the black scattering body 161j can be easily guided to the photovoltaic devices 2.

When a part of light, which has not been absorbed by the photovoltaic devices 2, penetrates the photovoltaic devices 2, the light having penetrated the photovoltaic devices 2 and entered into the sealing resin 42j or the black scattering body 162j is reflected, and re-enters into the photovoltaic devices 2, thereby enabling to guide the light to the photovoltaic devices 2 easily.

Accordingly, even in the second embodiment, in the solar battery module 100j, the majority of light in the visible region, among the light incident on the non-power generation region, is absorbed by the light scattering portion 16j to express black color, while light in the wavelength region other than the visible region is scattered by the light scattering portion 16j, and is caused to re-enter into the photovoltaic devices 2, thereby enabling to improve the use efficiency of light. That is, the power output of the solar battery module 100j can be improved, and the design characteristics of the solar battery module 100 can be improved.

In light guiding from the non-power generation region to the power generation region by light scattering, which has been used conventionally, light in all the visible regions is emitted from the glass into the air and seems white.

On the other hand, in the solar battery module 100j according to the second embodiment, an appropriate pigment or the like can be selected for the material of the light scattering portion 16j, and the light scattering body that absorbs a part of light in the visible region, which is a light absorption region of the photovoltaic device 2, and scatters other partial light can be used. Accordingly, because a part of light in the visible region having entered into the non-power generation region between the photovoltaic devices 2 is absorbed by the light scattering portion 16j, and the other partial light in the visible region is scattered by the light scattering portion 16j, the non-power generation region can have the color tone including blue, red, yellow, or the like other than white. That is, when the light absorption portion in the photovoltaic device 2 is not complete black and has a color tone including blue, red, yellow, or the like, the design characteristics can be improved by approximating the color tone of the non-power generation region to the color tone of the photovoltaic device 2, thereby enabling to realize the solar battery module 100j excellent in power output as well as in design.

Furthermore, according to the present embodiment, the solar battery cell having an electrode on both two principal surfaces of the solar battery cell is used. However, it is also possible to use a back contact cell in which there is no electrode on its principal surface, which becomes the main light receiving surface, and an electrode is arranged only on the principal surface on the opposite side.

A manufacturing method of the solar battery module 100j (the configuration example shown in FIG. 3-2) according to the second embodiment is explained next with reference to FIGS. 4-1 to 4-4, by using a monocrystalline silicon solar battery module that uses a monocrystalline silicon solar battery cell (hereinafter, “cell 2”) as the photovoltaic device 2 as an example. FIGS. 4-1 to 4-4 are sectional views for explaining the manufacturing method of the solar battery module 100j according to the second embodiment. In the following descriptions, features different from the manufacturing method shown in FIGS. 2-1 to 2-3 are mainly explained.

The sealing resins 41j1 and 42j1 do not necessarily have an irregular shape on the surface thereof. However, when scattering angle distribution of light scattering of the sealing resin 42j1 and the black scattering body 161j is small and scattering intensity with respect to a vertical direction is high with respect to a scattering surface, by providing the light scattering surfaces of the sealing resin 42j1 and the black scattering body 161j with an inclination with respect to the surface of the solar battery module 100j, a larger amount of light can be guided to the solar battery cell. Therefore, an example in which irregularities are provided on the surfaces of the sealing resin 42j1 and the black scattering body 161j is shown below. However, to simplify manufacturing, the surfaces thereof can be flat. For the purposes described above, it is not always necessary that the surface shape has a regular uneven structure.

In the process shown in FIG. 4-1, after a sheet-like sealing resin 41ji is placed on the transparent support body 1, the mold 21 having irregularities (see FIG. 2-2) is laid on the top of it, to apply pressure-molding on the sealing resin 41ji. Accordingly, a plurality of protrusions having the same shape as the protrusions 6a1 according to the first embodiment are formed on a surface opposite to the light incident side of the sealing resin 41j1. Other features are identical to those in the process shown in FIG. 2-1. Alternatively, an already embossed sealing resin can be used as the sealing resin 41j1.

In the process shown in FIG. 4-2, as the black scattering bodies 161j and 162j, for example, the Brown 10C873 pigment powder manufactured by Shepherd Color Company is put on the plurality of cells 2. At this time, the black scattering body powder having a particle size of 100 nanometers to 10 micrometers inclusive is used. Accordingly, the black scattering body 161j is arranged between the cells 2, the black scattering body 162j is arranged on the second principal surface 2b of each cell 2.

In the process shown in FIG. 4-3, the sheet-like sealing resin 42j1 is prepared. For example, as for the sealing resin 42j1, an ethylene-vinyl acetate resin (EVA) sheet on which the same material as that of the black light reflecting body 6 is kneaded is used. The mold having irregularities (see FIG. 2-2) is laid on the top of the surface on the light incident side of the sheet-like sealing resin 42j1, to apply pressure-molding on the sealing resin 42ji. Accordingly, a plurality of protrusions having the same shape as the protrusions 6a1 according to the first embodiment are formed on the surface on the light incident side of the sealing resin 42j1. The sheet-like sealing resin 42j1 is put on the cells 2. Alternatively, an already embossed sealing resin can be used as the sealing resin 42j1.

In the process shown in FIG. 4-4, pressure-molding by the mold 21 is not performed. Other features are identical to those in the process shown in FIG. 2-3.

As described above, in the manufacturing method of the solar battery module 100j according to the second embodiment, the black scattering body 161j is formed between the adjacent photovoltaic devices, and the black scattering body 162j is formed on the second principal surface 2b of the photovoltaic device 2. In the solar battery module 100j manufactured in this manner, the particle diameter of particles in each of the sealing resin 42j1 or the black scattering bodies 161j and 162j is equal to or larger than 100 nanometers, at which strong light scattering occurs, and equal to or smaller than several tens of micrometers at which light scattering intensity per volume is sufficiently large. As a result, light incident on the sealing resin 42j1 or the black scattering bodies 161j and 162j is scattered in various directions, and thus the amount of light having the incident angle of the scattered light to the surface of the solar battery module 100j larger than the critical angle can be increased. Accordingly, the scattered light can be totally reflected easily on the surface of the solar battery module 100j and guided to the photovoltaic devices 2.

Furthermore, when the solar battery cell 2 is a solar battery element or the like that can generate power on both surfaces and the entire surface of the main light incident side and the opposite surface are not covered with electrodes, because the sealing resin 42j1 and the black scattering body 162 are present as the light scattering body on the main light incident side and the opposite surface of the solar battery cell 2, by scattering and reflecting light that cannot be absorbed due to a small absorption coefficient of the solar battery cell and has penetrated therethrough by the sealing resin 42j1 and the black scattering body 162, the light having penetrated through the solar battery cell can be caused to re-enter into the solar battery and contribute to power generation.

Therefore, also in the second embodiment, in the solar battery module 100j, the majority of visible light, among the light incident on the non-power generation region, is absorbed by the sealing resin 42j1 and the light scattering portion 16j to express black color, while the majority of light in the wavelength region other than the visible region is scattered by the light scattering portion 16j, and is caused to re-enter into the photovoltaic devices 2, thereby enabling to improve the use efficiency of light. That is, the power output of the solar battery module 100j can be improved, and the design characteristics of the solar battery module 100j can be improved.

Furthermore, in the manufacturing method of the solar battery module 100j according to the second embodiment, the scattering body in the sealing resin 42j1 and the black scattering bodies 161j and 162j are made of a pigment. Accordingly, the voltage resistance between adjacent photovoltaic devices can be further improved and the manufacturing cost of the solar battery module 100j can be reduced, as compared to the case where the black light reflecting body is made of metal.

Each of the black scattering bodies 161j and 162j is made of a material including as a main component of at least one substance (one substance or a mixture of plural substances) selected from a group consisting of copper oxide, iron oxide, cobalt oxide, molybdenum oxide, manganese dioxide, chromium oxide, nickel oxide, iron titanate, titanium dioxide containing manganese, titanium dioxide containing antimony, iron oxide containing manganese, cadmium sulfide, cadmium selenide sulfide, copper chromium oxide, nickel iron oxide, nickel chromium oxide, cobalt aluminum oxide, cobalt chromium oxide, ferromanganese oxide, cobalt iron oxide, copper chromium oxide, zinc chromium oxide, zinc iron oxide, iron chromium oxide, copper iron manganese oxide, copper manganese chromium oxide, sodium aluminosilicate, lithium aluminosilicate, potassium aluminosilicate, sodium aluminosilicate sulfide, lithium aluminosilicate sulfide, potassium aluminosilicate sulfide, titanium dioxide, and cobalt phosphate.

### Third Embodiment

A solar battery module 100k according to a third embodiment is explained with reference to FIGS. 5-1 to 5-4. FIG. 5-1 is a plan view of the solar battery module 100k as viewed from the side of the light receiving surface 1a.

FIG. 5-2 is a sectional view of a configuration of the solar battery module 100k. FIG. 5-3 is an enlarged sectional view of a portion passing through a soldering bus electrode 12 in the photovoltaic device in the solar battery module 100k. FIG. 5-4 is an enlarged sectional view of a portion passing through the collecting electrode 8 in the photovoltaic device in the solar battery module 100k. In the following descriptions, elements different from those of the first and second embodiments are mainly explained.

The solar battery module 100k includes a light scattering portion 16k. The light scattering portion 16k includes a plurality of the black scattering bodies 161k and 162k. The black scattering bodies 161k and 162k respectively have wavelength selectivity such that the optical reflectivity is equal to or less than 15% over the wavelength region of 500 nanometers to 600 nanometers inclusive, and there is a region having an optical reflectivity larger than 15% in the wavelength region overlapping on the absorption wavelength range of the photovoltaic device 2 (crystalline silicon) in one of wavelength regions of equal to or less than 350 nanometers and equal to or larger than 700 nanometers. The respective black scattering bodies 161k and 162k respectively have a particle diameter of 100 nanometers to 10 micrometers inclusive.

As shown in FIGS. 5-3 and 5-4, the collecting electrode 8 and the soldering bus electrode 12 are arranged on the first principal surface 2a of the photovoltaic device 2. The inter-element connecting line 5 is bonded to the soldering bus electrode 12 via a solder 13. The light scattering portion 16k includes the black scattering body (a plurality of third light scattering bodies) 161k that covers the collecting electrode (the metal electrode) 8, and the black scattering body 162k that covers the inter-element connecting line 5. For example, Brown 10C873 pigment powder manufactured by Shepherd Color Company or the like can be used as the black light scattering bodies 161k and 162k that cover the electrode on the light receiving surface side. The black scattering bodies 161k and 162k can be formed by forming an electrode of approximately several tens of micrometers by an aluminum evaporation method using an evaporation mask on the surface on the light incident side of the solar battery cell and anodizing the electrode in a solution using perylene or the like. At this time, before performing aluminum evaporation, by roughening the surface of the solar battery by reactive ion etching using reactive gas such as SF6, an electrode having a large surface roughness can be acquired, and as a result, the light scattering property is manifested. In the method of using such a metal electrode directly as the black scattering body, it is not necessary that the black scattering body is formed to be matched with the position of the electrode. Therefore, it is advantageous that any alignment is not required, and a shadow area formed on the light receiving surface of the solar battery cell by the black scattering body can be reduced.

A region in which the collecting electrode 8 and the bus electrode 12 are not arranged on the first principal surface 2a of the photovoltaic device 2 can be covered with an antireflective film. The antireflective film is not always essential. Furthermore, the rear-surface electrode 9 is arranged on the second principal surface 2b of the photovoltaic device 2.

According to the third embodiment, it is desired that the particle diameter of particles in each of the black scattering bodies 161k and 162k be equal to or larger than 100 nanometers at which light scattering occurs, and equal to or smaller than several tens of micrometers at which light scattering intensity per volume is sufficiently large. Accordingly, light incident on the black scattering body 161k that covers the collecting electrode 8 on the first principal surface 2a of each photovoltaic device 2 is scattered in various directions, and thus the incident angle of the light scattered by the black scattering body 161k to the transparent support body 1 (glass) becomes larger than the critical angle θ easily, and the light scattered by the black scattering body 161k can be totally reflected easily. Accordingly, the light scattered by the black scattering body 161k can be easily guided to the photovoltaic devices 2.

Further, because the light incident on the black scattering body 162k that covers the inter-element connecting line 5 is scattered in various directions, the incident angle of the light scattered by the black scattering body 162k to the transparent support body 1 (glass) becomes larger than the critical angle θ easily, and the light scattered by the black scattering body 162k can be totally reflected easily. Accordingly, the light scattered by the black scattering body 162k can be easily guided to the photovoltaic devices 2.

Therefore, according to the third embodiment, in the solar battery module 100k, the color tone of the collecting electrode 8 and the inter-element connecting line 5 and the color tone of the light absorbing portion can be approximated on the surface on the light incident side of the photovoltaic device. Simultaneously, the majority of light in the wavelength region other than the visible region is caused to re-enter into the photovoltaic devices 2, thereby enabling to improve the use efficiency of light. That is, the power output of the solar battery module 100k can be improved, and the design characteristics of the solar battery module 100k can be improved.

A manufacturing method of the solar battery module 100k according to the third embodiment is explained by using a monocrystalline silicon solar battery module that uses a monocrystalline silicon solar battery cell (hereinafter, “cell 2”) as the photovoltaic device 2 as an example. In the example, a monocrystalline silicon solar battery is used as an example. However, a thin film solar battery such as an amorphous silicon solar battery or a cadmium telluride solar battery is also applicable when not only the transparent electrode but also the metal electrode and the like are used.

A texture structure having irregularities (not shown) is formed on the first principal surface 2a of a P-type monocrystalline silicon substrate 11 as a semiconductor substrate, in the cell 2 shown in FIG. 5-3. An N-type diffused layer on which heat of approximately 900° C. is applied to diffuse N-type impurities such as phosphorus by using phosphorous oxychloride as a raw material is formed in a range of a predetermined depth from the surface of the silicon substrate 11. Accordingly, a semiconductor PN junction is formed on the surface of the silicon substrate 11.

A phosphate glass formed on the surface is removed by hydrofluoric acid.

A silicon nitride film is formed on the first principal surface 2a of the silicon substrate 11 according to a chemical vapor deposition method, as an antireflective film 10 that prevents reflection of incident light, and thereafter, a paste containing a glass component and silver is printed on the first principal surface 2a of the silicon substrate 11 according to a screen printing method. Accordingly, a surface electrode (the electrode on the side of the light receiving surface 1a) is formed, which includes the collecting electrode (a grid electrode) 8 made of silver, provided in a comb shape for locally collecting a current (electrons) generated by the PN junction on the surface of the monocrystalline silicon substrate 11, and the soldering bus electrode 12 made of silver or the like, provided substantially orthogonal to the collecting electrode 8, to connect the collecting electrodes 8 with each other in order to take out the current collected by the collecting electrode 8.

Meanwhile, the rear-surface electrodes 9 and 12 made of aluminum or silver for taking out a current to outside, which are provided substantially on the entire surface of the second principal surface 2b of the P-type silicon substrate 11, are formed on the second principal surface 2b of the P-type silicon substrate 11, in order to collect electrical power generated by the PN junction, according to the screen printing method.

Thereafter, the electrode is fired by heating the electrode at a temperature of approximately 800° C., and the antireflective film is corroded to connect the electrode and the semiconductor substrate.

Subsequently, the Black 411A pigment manufactured by Shepherd Color Company is mixed and kneaded in a solution of acetylacetone and acetic acid to produce a paste, and the paste is printed as the black scattering body 161k that covers the collecting electrode 8 according to the screen printing method. At this time, the paste including particles having a particle diameter of 100 nanometers to 10 micrometers inclusive is used. The substrate is then heated to blow components other than the pigment and is dried.

A copper wire as the inter-element connecting line 5 is spanned over between the electrode (the surface bus electrode 12) on the first principal surface 2a of one cell 2 of two cells 2 and the electrode (the rear-surface electrode 12) on the second principal surface 2b of the other cell 2 (between the negative electrode and the positive electrode), and the respective electrodes and the copper wire are soldered by the solder 13. Accordingly, one cell 2 and the other cell 2 are electrically connected.

Thereafter, a mask is put on the portion other than the copper wire of the inter-element connecting line 5, to apply the paste containing a pigment, which has been diluted, by spraying, so that only the copper wire portion becomes black. The substrate is then heated to approximately 200° C. to blow the components other than the pigment and is dried.

Subsequently, the processes shown in FIGS. 2-1 to 2-3 and/or the processes shown in FIGS. 4-1 to 4-3 are performed.

As described above, in the manufacturing method of the solar battery module 100k according to the third embodiment, the light black scattering body 161k and the black scattering body 162k are formed in a region covering the collecting electrode (the metal electrode) 8 and the inter-element connecting line 5. At this time, the particle diameter of particles in each of the black scattering bodies 161k and 162k are equal to or larger than 100 nanometers, at which light scattering occurs, and equal to or smaller than several tens of micrometers at which light scattering intensity per volume is sufficiently large. As a result, light incident on the black scattering bodies 161k and 162k is scattered in various directions, and thus the light scattered by the black scattering bodies 161k and 162k can be totally reflected easily on the surface of the solar battery module 100k, and can be easily guided to the photovoltaic devices 2.

Therefore, according to the third embodiment, in the solar battery module 100k, the color tone of the collecting electrode 8 and the inter-element connecting line 5 and the color tone of the light absorbing portion can be approximated on the surface on the light incident side of the photovoltaic device. Simultaneously, light in the wavelength region other than the visible region is scattered by the black scattering bodies 161k and 162k and is caused to re-enter into the photovoltaic devices 2, thereby enabling to improve the use efficiency of light. That is, the power output of the solar battery module 100k can be improved, and the design characteristics of the solar battery module 100k can be improved.

According to the third embodiment, the collecting electrode and the black light scattering body are formed separately. However, it is not always necessary that these elements are formed separately, and can be in such a state that the metal component as the electrode and the particles of the black scattering body are mixed.

Furthermore, for example, the black light scattering body 6 that covers the electrode can be formed by forming the collecting electrode 8 on the surface on the light incident side by the aluminum evaporation method using the evaporation mask, and anodizing the electrode in a solution using perylene or the like. As the blackening means, not only oxidation but also sulfurization can be used. In the method of using such a metal electrode directly as the black scattering body, it is not necessary that the black scattering body is formed to be matched with the position of the electrode. Therefore, it is advantageous that any alignment is not required, and a shadow area formed on the light receiving surface of the solar battery cell by the black scattering body can be reduced.

Further, it is not always necessary that the light scattering portion is in contact with the metal electrode, and can be formed to be away from the metal electrode, and for example, can be embedded in the sealing resin 41.

Each of the black scattering bodies 161k and 162k is made of a material including as a main component of at least one substance (one substance or a mixture of plural substances) selected from a group consisting of copper oxide, iron oxide, cobalt oxide, molybdenum oxide, manganese dioxide, chromium oxide, nickel oxide, iron titanate, titanium dioxide containing manganese, titanium dioxide containing antimony, iron oxide containing manganese, cadmium sulfide, cadmium selenide sulfide, copper chromium oxide, nickel iron oxide, nickel chromium oxide, cobalt aluminum oxide, cobalt chromium oxide, ferromanganese oxide, cobalt iron oxide, copper chromium oxide, zinc chromium oxide, zinc iron oxide, iron chromium oxide, copper iron manganese oxide, copper manganese chromium oxide, sodium aluminosilicate, lithium aluminosilicate, potassium aluminosilicate, sodium aluminosilicate sulfide, lithium aluminosilicate sulfide, potassium aluminosilicate sulfide, titanium dioxide, and cobalt phosphate.

Further, instead of at least one of the black scattering bodies 161k and 162k, a black light reflecting body can be used. That is, the body that covers the collecting electrode (the metal electrode) 8 can be the black light reflecting body instead of the black scattering body 161k. The body that covers the inter-element connecting line 5 can be the black light reflecting body instead of the black scattering body 162k. The black light reflecting body can be made of a material including as a main component of at least one substance selected from a group consisting of tin, nickel, aluminum, zinc, titanium, copper, silver, and gold. That is, the black scattering body can be formed by oxidizing (anodizing or the like) at least one surface of at least one substance (one type of metal or an alloy of plural types of metal) selected from the group consisting of tin, nickel, aluminum, zinc, titanium, copper, silver, and gold. For example, the black light reflecting body can be made of aluminum (an aluminum foil) to which blackening processing by anodization is performed, or titanium whose surface is oxidized to a thickness of approximately 20 nanometers to 60 nanometers and displays blue due to interference of light, as shown in Japanese Patent Application Laid-open No. 2008-13833. Specifically, as the collecting electrode 8, electrodes having a thickness of approximately several tens of micrometers can be formed in a grid form on the surface on the light incident side of the solar battery cell by the aluminum evaporation method using the evaporation mask, and anodizing the electrode in a solution using perylene or the like. At this time, for example, when monocrystalline silicon including 100 surfaces as the light receiving surface is used as the photovoltaic device, before aluminum evaporation, the surface of the solar battery is subjected to anisotropic etching in a solution of sodium hydroxide added with isopropyl alcohol, thereby forming the structure on the silicon surface in a pyramid shape. Accordingly, an electrode having an inclined surface with respect to a planar direction of the substrate can be formed, and as a result, the angle of reflected light can be an angle equal to or larger than the critical angle of a translucent material on the module surface. In the method of using such a metal electrode directly as a black reflecting body, it is not necessary that the black reflecting body is formed to be matched with the position of the electrode. Therefore, it is advantageous that any alignment is not required, and a shadow area formed on the light receiving surface of the solar battery cell by the black reflecting body can be reduced.

In this example, the black light reflecting body is pressure-molded so that the surface on the light incident side of the black light reflecting body includes at least one protrusion having a reflecting surface inclined with an angle equal to or larger than α satisfying the expression (3) with respect to the light receiving surface 1a of the transparent support body 1. Accordingly, light having a wavelength other than the visible light, among light incident on the first principal surface of the photovoltaic device, is reflected by the black light reflecting body so as to enter into the light receiving surface 1a of the transparent support body 1 with an angle larger than the critical angle of the interface between the solar battery module and the air. As a result, the reflected light can be totally reflected on the interface between the solar battery module and the air, and can contribute to power generation.

### INDUSTRIAL APPLICABILITY

As described above, the solar battery module, the photovoltaic apparatus, and the manufacturing method of a solar battery module according to the present invention are useful for a photovoltaic device that is used in a state of a module.

### REFERENCE SIGNS LIST

1 transparent support body
1a light receiving surface
2 photovoltaic device
2a first principal surface
2b second principal surface
3, 3i weather-resistant polymeric film
5 inter-element connecting line
6, 6i black light reflecting body
6a1 protrusion
6a11, 6a12 reflecting surface
8 collecting electrode
9 rear-surface electrode
10 antireflective film
11 silicon substrate
12 bus electrode
13 solder
16j, 16k light scattering portion
41, 41i, 41j, 41j1, 42, 42i, 42j, 42j1 sealing resin
42ja1 protrusion
42ja11, 42ja12 reflecting surface
100, 100j, 100k solar battery module
161j, 162j, 161k, 162k black scattering body
DA device array

1-21. (canceled)

22. A solar battery module comprising:
a device array in which a plurality of photovoltaic devices respectively having a first principal surface on a side to which light mainly enters and a second principal surface on an opposite side to the side to which light mainly enters, and respectively having an optical reflectivity of equal to or less than approximately 10% in a wavelength region of 500 nanometers to 600 nanometers inclusive are arranged;
a substrate that has optical transparency and is arranged on a light incident side with respect to the device array;
a first sealing portion that has optical transparency and is arranged between the device array and the substrate;
a rear-surface protective member that is arranged on an opposite side to the light incident side with respect to the device array;
a second sealing portion that is arranged between the device array and the rear-surface protective member; and
a coloring portion that is arranged in a region corresponding to a gap between the photovoltaic devices in inside of at least one of the first sealing portion, the second sealing portion, the rear-surface protective member, and the substrate, and having an optical reflectivity of equal to or less than 15% over a wavelength region of 500 nanometers to 600 nanometers inclusive, wherein
exterior color tones of the respective photovoltaic devices and a portion between the photovoltaic devices match one another in the solar battery module,
the coloring portion has a region in which an optical reflectivity becomes larger than 15% wavelength-selectively in a wavelength region overlapping on an absorption wavelength range of the photovoltaic device in one of wavelength regions of equal to or less than 350 nanometers and equal to or larger than 700 nanometers, and
total integrated scattering of the coloring portion becomes equal to or larger than 50% in the wavelength region overlapping on an absorption wavelength range of the photovoltaic device in one of wavelength regions of equal to or less than 350 nanometers and equal to or larger than 700 nanometers.

23. The solar battery module according to claim 22, wherein the plurality of photovoltaic devices is respectively capable of generating power by light entering into any of the first principal surface and the second principal surface.

24. The solar battery module according to claim 23, wherein
the coloring portion includes
a first light scattering body that has wavelength selectivity and is arranged between the photovoltaic devices, and
a second light scattering body that has wavelength selectivity and is arranged on the second principle surface of the photovoltaic device.

25. A solar battery module comprising:
a device array in which a plurality of photovoltaic devices respectively having a first principal surface on a side to which light mainly enters and a second principal surface on an opposite side to the side to which light mainly enters, while respectively being capable of generating power by light entering into any of the first principal surface and the second principal surface are arranged;
a substrate that has optical transparency and is arranged on a light incident side with respect to the device array;
a first sealing portion that is sealed by a first sealing resin having optical transparency and is arranged between the device array and the substrate;
a rear-surface protective member that is arranged on an opposite side to the light incident side with respect to the device array; and
a second sealing portion that is sealed by a second sealing resin arranged between the device array and the rear-surface protective member, wherein
the first sealing portion and the second sealing portion form an interface on which the first sealing resin and the second sealing resin come in contact with each other in a region corresponding to a gap between the photovoltaic devices,
the second sealing resin is colored by containing a blue or purple pigment,
the second sealing resin has wavelength selectivity such that an optical reflectivity is equal to or less than 15% over a wavelength region of 500 nanometers to 600 nanometers inclusive, and there is a region having an optical reflectivity larger than 15% in a wavelength region overlapping on an absorption wavelength range of the photovoltaic device in one of wavelength regions of equal to or less than 350 nanometers and equal to or larger than 700 nanometers, and
total integrated scattering of the second sealing resin becomes equal to or larger than 50% in the wavelength region overlapping on the absorption wavelength range of the photovoltaic device in one of the wavelength regions of equal to or less than 350 nanometers and equal to or larger than 700 nanometers.

26. A solar battery module comprising:
a device array in which a plurality of photovoltaic devices respectively having an optical reflectivity of equal to or less than approximately 10% in a wavelength region of 500 nanometers to 600 nanometers inclusive are arranged;
a substrate that has optical transparency and is arranged on a side to which light mainly enters with respect to the device array;
a first sealing portion that has optical transparency and is arranged between the device array and the substrate;
a rear-surface protective member that is arranged on an opposite side to the side to which light mainly enters with respect to the device array;
a second sealing portion that is arranged between the device array and the rear-surface protective member; and
a coloring portion that is arranged in a region corresponding to a gap between the photovoltaic devices in inside of at least one of the first sealing portion, the second sealing portion, the rear-surface protective member, and the substrate, and having an optical reflectivity of equal to or less than 15% over a wavelength region of 500 nanometers to 600 nanometers inclusive, wherein
exterior color tones of the respective photovoltaic devices and a portion between the photovoltaic devices match one another in the solar battery module,
the coloring portion has a region in which the optical reflectivity becomes larger than 15% wavelength-selectively in a wavelength region overlapping on an absorption wavelength range of the photovoltaic device in one of wavelength regions of equal to or less than 350 nanometers and equal to or larger than 700 nanometers,
total integrated scattering of the coloring portion becomes less than 50% in the wavelength region overlapping on the absorption wavelength range of the photovoltaic device in one of wavelength regions of equal to or less than 350 nanometers and equal to or larger than 700 nanometers, and
a surface on a light incident side in the coloring portion includes a plurality of slope faces respectively having a reflecting surface inclined with an angle equal to or larger than α, which satisfies:
α=(arcsin(1/n))/2
with respect to a light receiving surface of the substrate, when a refractive index of a medium in contact with the light reflecting portion is designated as n.
